(19) United States
(12) Patent Application Publication
(10) Pub. No.: US 2007/0205417 A1
(43) Pub. Date: Sep. 6, 2007

(54) LIGHT-EMITTING ELEMENT, LIGHT-EMITTING DEVICE, LIGHTING DEVICE, AND ELECTRONIC APPLIANCE

(75) Inventors: Hiroki Ohara, Koza (JP); Junichiro Sakata, Atsugi (JP); Yasuo Nakamura, Tokyo (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/679,466

(22) Filed: Feb. 27, 2007

(30) Foreign Application Priority Data
Mar. 2, 2006 (JP) 2006-056994

(51) Int. Cl. H01L 33/00

(52) U.S. Cl. 257/79

(57) ABSTRACT

The light-emitting layer contains a light-emitting base including a chalcogenide compound, and a light-emitting center including two kinds of halogen compounds. The chalcogenide compound contains a chalcogen element and an element selected from elements belonging to Group 2 to Group 13 of the periodic table, and the halogen compound contains a halogen element and an element selected from typical metal elements, transition metal elements, or rare earth elements.

### TECHNICAL FIELD

The present invention relates to a light-emitting element utilizing electroluminescence. In addition, the present invention relates to a light-emitting device, a lighting device, and an electronic appliance each having the light-emitting element.

### BACKGROUND ART

In recent years, thin and flat display devices are demanded as display devices for a television, a cellular phone, a digital camera, and the like. A display device utilizing a self-luminous light-emitting element is attracting attention as a display device for meeting this requirement. A light-emitting element utilizing electroluminescence is one of self-luminous light-emitting elements, in which a light-emitting material is interposed between a pair of electrodes and a voltage is applied thereto so that light emission from the light-emitting material can be obtained.

Such a self-luminous light-emitting element has advantages over a liquid crystal display element, such as high visibility of a pixel and no need of backlight, and is considered suitable for a flat panel display element. In addition, such a light-emitting element can be manufactured to be thin and light-weight, which is also a great advantage. Furthermore, the response speed is extremely high, which is another feature of this light-emitting element.

Furthermore, a self-luminous light-emitting element like this can be formed into a film; therefore, by forming an element with a large area, plane light emission can be easily obtained. This feature is difficult to be obtained from a point light source typified by an incandescent lamp or an LED, or a line light source typified by a fluorescent lamp. Accordingly, a utility value of the self-luminous light-emitting element as a plane light source which can be applied to a lighting system and the like is high.

Light-emitting elements utilizing electroluminescence are classified into two groups, according to whether the light-emitting material is an organic compound or an inorganic compound. In general, the former is referred to as an organic EL element, and the latter is referred to as an inorganic EL element.

Inorganic EL elements are classified, according to their element structures, into a dispersed inorganic EL element and a thin-film inorganic EL element. They are different from each other in that the former includes a light-emitting layer in which particles of a light-emitting material are dispersed in a binder and the latter includes a light-emitting layer formed of a thin film of a phosphor material. However, their mechanisms are common, and light emission is obtained through collision excitation of a base material or a luminescent center by electrons accelerated by a high electric field. For such a reason, a high electric field is necessary for a general inorganic EL element to provide light emission, and it is necessary to apply a voltage of several hundred volts to a light-emitting element. For example, an inorganic EL element that emits high luminance blue light which is necessary for a full-color display has been developed in recent years; however, it requires a driving voltage of 100 to 200 V (for example, refer to Reference 1: Japanese Journal of Applied Physics, 1999, Vol. 38, p. L1291). Therefore, the inorganic EL element consumes much power, and is difficult to be employed for a small-to-medium-sized display, for example, a display of a cellular phone or the like.

### DISCLOSURE OF INVENTION

In view of the foregoing problem, an object of the present invention is to provide a light-emitting element capable of light emission of mixed colors, a light-emitting device utilizing the light-emitting element, and a lighting device utilizing the light-emitting element Also, an object is to provide a light-emitting device and an electronic appliance utilizing these.

One aspect of the present invention is a light-emitting device which comprises a first electrode; a light-emitting layer formed over the first electrode and comprising a compound represented by a composition formula of MX, an acceptor, a first donor, a second donor; and a second electrode formed over the light-emitting layer. The compound has a crystal structure. M is an element selected from the group consisting of elements belonging to Group 2 to Group 13 of the periodic table. X is a chalcogen element. The acceptor is an ion having lower valence than M. The light-emitting layer may further comprise another acceptor which is an ion having lower valence than M. Each of the first and second donors may be an ion having lower valence than X. M may be composed of two or more elements belonging to Group 2 to Group 13 of the periodic table. Further, the crystal structure includes at least one unit cell. A crystal system of the unit cell is one of cubic system, hexagonal system, tetragonal system, orthorhombic system, monoclinic system, and triclinic system, or a combination thereof. Furthermore, the compound is one selected from the group consisting of ZnO, ZnS, ZnSe, MgS, CaS, SrS, and ZnMgS.

In the present invention, a variety of luminescence center compounds are utilized in manufacturing a light emitter of a light-emitting element. The light emitter is a fluorescent body with a chalcogenide compound as a base and to which a halogen element is added as a fluorescence center compound. Conventionally, zinc sulfide (ZnS) which is one chalcogenide compound is utilized as the base and copper chloride (I) (CuCl) which is one halogen compound is utilized as the luminescence center; however, the light emitter is not bound by these materials and has equivalent or better characteristics of a conventional light emitter. In the foregoing structure, the chalcogenide compound that becomes the base of the light emitter is a compound including a chalcogen element in Group 16 of the periodic table, that is, oxygen (O), sulfur (S), selenium (Se), tellurium (Te), or polonium (Po), and a metal element belonging to Group 2 to Group 13 of the period table. As examples, zinc oxide (ZnO), zinc sulfide (ZnS), zinc selenide (ZnSe), magnesium sulfide (MgS), calcium sulfide (CaS), or strontium sulfide (SrS) can be given. Also, a composite material such as SrGa₂S₄ or ZnMgS in which two or more kinds of chalcogenide compounds are mixed may be used.

Also, in the foregoing structure, the halogen compound is a compound including a halogen element in Group 17 of the periodic table, that is, fluorine (F), chlorine (Cl), bromine (Br), iodine (I), or astatine (At). For example, the halogen compound is a compound further including at least one of the following in the periodic table: copper (Cu), silver (Ag), or gold (Au) in Group 11 which is a transition metal element; cerium (Ce), samarium (Sm), europium (Eu), terbium (Tb), or thulium (Tm) which is a rare earth element; aluminum (Al) or gallium (Ga) which is a typical metal element; or the like. Since a copper ion in a copper compound can become monovalent or bivalent, copper fluoride (I) (CuF), copper fluoride (II) (CuF₂), copper chloride (I) (CuCl), copper chloride (II) (CuCl₂), copper bromide (I) (CuBr), copper bromide (II) (CuBr₂), copper iodide (1) (CuI), copper iodide (II) (CuI₂), or the like is given. Also, as a silver compound, silver fluoride, silver chloride, silver bromide (AgBr), silver iodide (AgI), or the like is given. The silver compound can be utilized without being bound to valence as with a copper ion. Further, a composite material in which two or more kinds of halogen compounds like the foregoing are mixed may be used.

This invention relates to a light-emitting element including a first electrode, a light-emitting layer over the first electrode, and a second electrode over the light-emitting layer. The light-emitting layer includes a chalcogen element and a halogen element.

Also, the present invention relates to a light-emitting element including a first electrode, a first dielectric film over the first electrode, a light-emitting layer over the first dielectric film, a second dielectric film over the light-emitting layer, and a second electrode over the second dielectric film. The light-emitting layer includes a chalcogen element and a halogen element.

In the present invention, a luminescence base of the light-emitting layer is formed of one kind or two or more kinds of chalcogenide compounds each containing the chalcogen element and an element belonging to Group 2 to Group 13 of the periodic table.

In the present invention, a luminescence center of the light-emitting layer is formed of one kind or two or more kinds of halogen compounds each containing the halogen element and a typical metal element, a transition metal element, or a rare earth element.

Also, the present invention relates to a light-emitting element including a first electrode, a light-emitting layer over the first electrode, and a second electrode over the light-emitting layer. The light-emitting layer includes at least two kinds of halogen elements.

Furthermore, the present invention relates to a light-emitting element including a fist electrode, a first dielectric film over the first electrode, a light-emitting layer over the first dielectric film, a second dielectric film over the light-emitting layer, and a second electrode over the second dielectric film. The light-emitting layer includes at least two kinds of halogen elements.

In the present invention, the light-emitting layer includes at least two kinds of elements selected from typical metal elements, transition metal elements, and rare earth elements as additive materials.

Also, the present invention relates to a light-emitting device including the foregoing light-emitting element.

Further, in the present invention, the light-emitting device mentioned above can be used for a lighting device.

Furthermore, the present invention relates to an electronic appliance that uses the light-emitting device mentioned above in a display portion.

Furthermore, the present invention includes a light-emitting device having the above-described light-emitting element. The light-emitting device in this specification includes in its category an image display device, a light-emitting device, or a light source (including a lighting device). In addition, the light-emitting device of the present invention includes: a module in which a connector such as an FPC (flexible printed circuit), a TAB (tape automated bonding) tape, or a TCP (tape carrier package) is attached to a panel provided with a light-emitting element; a module having a TAB tape or a TCP provided with a printed wiring board at an end thereof; and a module having an IC (integrated circuit) directly mounted on a light-emitting element by a COG (chip on glass) method.

The present invention includes an electronic appliance using a light-emitting element of the present invention for the display portion. Accordingly, the electronic appliance of the present invention includes a display portion provided with the above-described light-emitting element and a control means for controlling light emission of the light-emitting element.

For the light-emitting element of the present invention, a light-emitting layer can be formed of a chalcogenide compound and a halogen compound. Also, mixed color and white color light emissions instead of single color light emission are possible with the light-emitting element of the present invention.

In a case of an ion having a d orbital such as a transition metal, there is a difference in crystal field splitting depending on whether a ligand forms a six-coordination of a regular octahedron or a four-coordination of a regular tetrahedron, in a crystal lattice with respect to a metal ion; however, it is known that there is a difference in how great an influence of the ligand is on the crystal field splitting of a transition metal depending on spectrochemical order, in addition. If fluorine (F), chlorine (Cl), Bromine (Br), and iodine (I) are considered as ligands, the degree of energy of crystal field splitting depends on the type of ligand even if ions are anions of the same valence, and it is known that the degree of the energy is I⁻<Br⁻<Cl⁻<F⁻. That is, by having different halogen elements, energy levels are different, and mixed color light emission is possible by a light emission spectrum shifting to a long-wavelength side or a short-wavelength side, or by obtaining a wider range of a peak. Further, it is also possible to obtain white color light emission from a combination of this mixed color light emission or with a wider range of the spectrum.

### BRIEF DESCRIPTION OF DRAWINGS

In the following drawings:

FIGS. 1A to 1C each describe a light-emitting element of the present invention;

FIG. 2 describes a light-emitting device of the present invention;

FIGS. 3A and 3B each describe a light-emitting device of the present invention;

FIGS. 4A to 4D each describe an electronic appliance of the present invention;

FIG. 5 describes an electronic appliance of the present invention;

FIGS. 6A to 6C each describe an electronic appliance of the present invention;

FIG. 7 describes an electronic appliance of the present invention;

FIG. 8 describes an electronic appliance of the present invention;

FIG. 9 describes a light-emitting element of the present invention;

FIG. 10 describes a light-emitting device of the present invention;

FIG. 11 describes a light-emitting device of the present invention;

FIG. 12 describes a light-emitting device of the present invention;

FIGS. 13A and 13B each describe a light-emitting device of the present invention; and

FIGS. 14A and 14B each describe a light-emitting device of the present invention.

### BEST MODE FOR CARRYING OUT THE INVENTION

Embodiment Modes of the present invention will be explained below with reference to the drawings. However, it is to be easily understood by those skilled in the art that the present invention is not limited to the description below and the modes and details of the present invention can be changed in various ways without departing from the spirit and scope of the present invention. Therefore, the present invention should not be interpreted as being limited to the description of Embodiment Modes below.

### Embodiment Mode 1

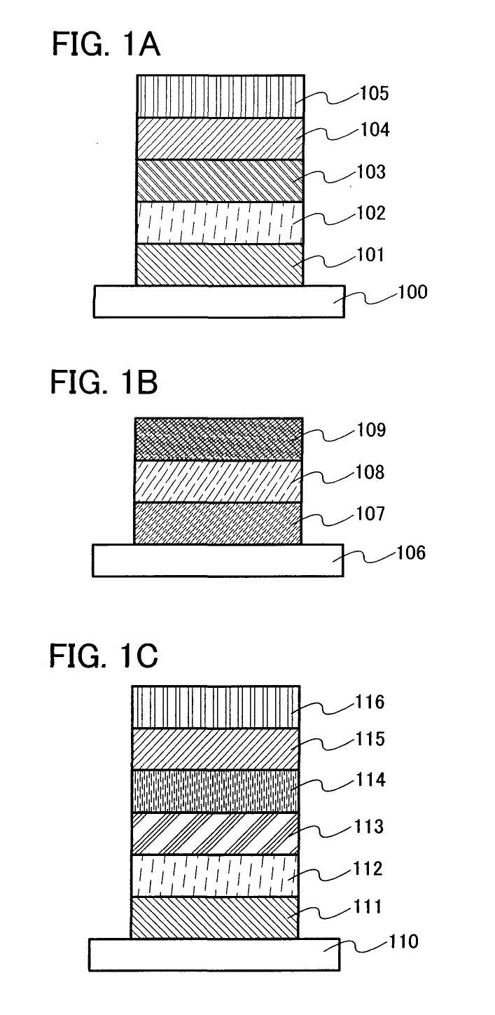

In this embodiment mode, a thin film light-emitting element according to the present invention is described with reference to FIGS. 1A to 1C.

A light-emitting element described in this embodiment mode has an element structure in which a first electrode 101 and a second electrode 105 are provided over a substrate 100, with a first dielectric layer 102, a light-emitting layer 103, and a second dielectric layer 104 interposed between the first electrode 101 and the second electrode 105. Note that in this embodiment mode, the first electrode 101 and the second electrode 105 will be described below with an assumption that either may function as an anode or a cathode.

The substrate 100 is used as a supporting base of the light-emitting element. For the substrate 100, glass, quartz, plastic, or the like can be used, for example. Note that something other than this can be used if it functions as a supporting base in a manufacturing process of the light-emitting element.

For the first electrode 101 and the second electrode 105, a metal, an alloy, a conductive compound, a mixture thereof, or the like can be used. Specifically, an example thereof is indium tin oxide (ITO), indium tin oxide containing silicon or silicon oxide, indium zinc oxide (IZO), indium tin oxide containing tungsten oxide and zinc oxide (IWZO), or the like. These conductive metal oxide films are generally formed by sputtering. For example, indium zinc oxide (IZO) can be formed by sputtering using a target in which zinc oxide of 1 to 20 wt % is added to indium oxide. Indium tin oxide containing tungsten oxide and zinc oxide (IWZO) can be formed by sputtering using a target containing tungsten oxide of 0.5 to 5 wt % and zinc oxide of 0.1 to 1 wt % with respect to indium oxide. Alternatively, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), a nitride of a metal material (for example, titanium nitride (TiN)), or the like can be used. It is to be noted that in the case where the first electrode 101 and/or the second electrode 105 are/is formed to have a light-transmitting property, a film of a material with low visible light transmittance can also be used for a light-transmitting electrode when formed with a thickness of approximately 1 nm to 50 nm, preferably, 5 nm to 20 nm. It is to be noted that the electrode can also be formed by vacuum evaporation, CVD, or a sol-gel method other than sputtering.

However, since light emission is extracted to the outside by passing through the first electrode 101 or the second electrode 105, it is necessary that at least one of them be formed of a light-transmitting material. Also, it is preferable that a material be selected so that a work function of the first electrode 101 is larger than that of the second electrode 105. Further, it is not necessary that the first electrode 101 and the second electrode 105 each have a single-layer structure, and a structure with two or more layers may be employed.

There is no problem as long as a known material is used for the first dielectric layer 102 and the second dielectric layer 104, but it is particularly favorable to use a material with a high dielectric constant. For these dielectric layers, an organic material or an inorganic material may be used. For example, if an organic material is used, an acetal resin, an epoxy resin, methyl methacrylate, polyester, polyethylene, polystyrene, or cyano ethyl cellulose can be used. If an inorganic material is used, a nitride such as aluminum nitride (AlN), boron nitride (BN), or an oxide such as barium titanate (BaTiO₃), strontium titanate (SrTiO₃), lithium titanate (LiTiO₃), lead titanate (PbTiO₃), tantalum pentoxide (Ta₂O₅), bismuth oxide (Bi₂O₃), calcium titanate (CaTiO₃), potassium niobate (KNbO₃), silicon oxide (SiO₂), or aluminum oxide (Al₂O₃) can be given. Also, the material may be a composite material of these inorganic materials. Further, it is not necessary that the first dielectric layer 102 and the second dielectric layer 104 be each one layer, and two or more layers thereof may be provided. Furthermore, film thickness of each of the first dielectric layer 102 and the second dielectric layer 104 is 1 nm to 10000 nm, preferably 300 nm to 800 nm.

In the light-emitting layer 103, a base material that is a semiconductor may be used. A chalcogenide compound is used in particular, such as an oxide, a sulfide, or a selenide containing a metal element belonging to Group 2 to Group 13 of the periodic table. For example, zinc sulfide (ZnS), copper sulfide (Cu₂S), aluminum sulfide (Al₂S₃), calcium sulfide (CaS), strontium sulfide (SrS), zinc sulfide (ZnS), magnesium sulfide (MgS), or the like can be given as the sulide. As the oxide, zinc oxide (ZnO), yttrium oxide (Y₂O₃), gallium oxide (Ga₂O₃), or the like can be given. As the selenide, zinc selenide (ZnSe), cadmium selenide (CdSe), barium selenide (BaSe), or the like can be given. Furthermore, a composite material in which two or more kinds of these chalcogenide compounds are mixed can also be used. For example, a composite material such as SrGa₂S₄, ZnMgS, Y₂O₂S, or Zn₂SiO₄, can be given. Film thickness of the light-emitting layer is 10 nm to 1000 nm, preferably 30 nm to 500 nm.

In the light-emitting layer 103, a material that becomes a luminescence center is added other than the chalcogenide compound that becomes the base. A halogen compound can be given as an additive material. The halogen compound is a compound containing a halogen element in Group 17 of the periodic table, that is, fluorine (F), chlorine (Cl), bromine (Br), iodine (I), or astatine (At). Also, for example, the halogen compound is a compound further containing at least one of the following in the periodic table: copper (Cu), silver (Ag), and gold (Au) in Group 11 which are transition metals; and cerium (Ce), samarium (Sm), europium (Eu), terbium (Tb), and thulium (Tm) which are rare earth elements. As a copper compound, there is copper fluoride (CuF), copper chloride (CuCl), copper bromide (CuBr), copper iodide (CuI), or the like. Also, the halogen compound may be a halogen compound using a typical metal element such as aluminum (Al) or gallium (Ga). Further, a composite material in which two or more kinds of halogen compounds such as those above are mixed may be used as the luminescence center. The halogen compound has a mechanism of light emission where fluorine (F), chlorine (Cl), bromine (Br), or iodine (I) functions as a donor, and the typical metal element, the transition metal, or the rare earth element functions as an acceptor, and light is emitted by recombination of the donor and the acceptor.

As the additive material of the light-emitting layer, a plurality of the foregoing halogen compounds may be added to the base material of the light-emitting layer. For example, in a case of using zinc sulfide (ZnS) as the base material of the light-emitting layer, copper iodide (I) (CuI) can be added as the additive material at the same time as adding copper chloride (I) (CuCl). Consequently, instead of just obtaining light emission by copper chloride, light emission by copper iodide with a different energy level can also be obtained, and mixed color light emission can be obtained as a result. Also, instead of concurrently adding different halogen compounds of the same metal such as copper chloride (I) and copper iodide (I), halogen compounds of different metals can be added concurrently. For example, mixed color light emission can also be obtained by concurrently adding silver chloride (AgCl) and manganese chloride (II) (MnCl₂) with respect to zinc sulfide (ZnS) of the base material. Further, different halogen compound of different metals can be added concurrently. For example, mixed color light emission can be obtained by concurrently adding copper chloride (CuCl) and manganese fluoride (II) (MnF₂) with respect to zinc sulfide (ZnS) of the base material.

The light-emitting element according to the present invention is not limited to have the foregoing structure, and with regard to the dielectric layers over the electrodes, it may be that just one dielectric layer is formed over either the first electrode or the second electrode. Also, as shown in FIG. 1B, the structure may be that in which just a light-emitting layer 108 is provided between a first electrode 107 and a second electrode 109, over a substrate 106, and not include a dielectric layer. Furthermore, in the structure of not including a dielectric layer, a p-type semiconductor and an n-type semiconductor may be stacked between the first electrode and the second electrode, and one or both of the semiconductors may be a light-emitting layer.

In a case of using the additive materials in a semiconductor material according to the present invention, the additive material is made to be contained in the sulfide by a solid-state reaction, that is, by a method in which the sulfide and the additive material are weighed, mixed in a mortar so that grain diameters are sufficiently small, uniform, and dispersed, and then reacted in an electric furnace by heating. A baking temperature is preferably 500° C. to 2000° C. This is because a solid state reaction does not proceed when the temperature is too low and the base material is decomposed when the temperature is too high. Note that although baking in a powder form may be carried out, the baking is preferably carried out in a pellet form in which the powder is thickened. Also, pre-baking may be carried out first at a high temperature, and then baking at a lower temperature after adding the additive material may be carried out. The base material may be baked during baking for the first time, and during baking for the second time, the additive material may be added and baked. Further, in a case of carrying out the solid-state reaction, the reaction may be carried out under atmospheric pressure, in a rare gas atmosphere of argon (Ar) or the like or in an atmosphere of nitrogen (N₂), oxygen (O₂), hydrogen sulfide (H₂S), or the like. Furthermore, there is a case in which it is preferable to carry out baking in a vacuum state, and the material is contained in quartz tube or the like under a vacuum atmosphere and then baked. Still further, the material is contained in a quartz tube in a vacuum state, and the baking can be carried out according to a chemical transport method of utilizing a temperature distribution of an electric furnace for baking. The base material is activated by carrying out baking in the manner described above. The base material is represented by a composition formula MX (M is an element selected from the group consisting of elements belonging to Group 2 to Group 13 of the periodic table, and X is a chalcogen element) for example. After the baking, in the crystal structure of the base material (The crystal structure includes at least one unit cell. A crystal system of the unit cell is one of cubic system, hexagonal system, tetragonal system, orthorhombic system, monoclinic system, and triclinic system, or a combination thereof), a first lattice point of X is replaced by the first halogen element, and a second lattice point of X is replaced by the second halogen element. Each of the first and second halogen elements is an element contained in a material that becomes a luminescence center, and behaves like a donor. A metal, such as a typical metal or a transition metal contained in the material that becomes a luminescence center, replaces at least one of lattice points of M, or enters interstices in the crystal structure, and behaves like an acceptor. An acceptor making a pair with the first halogen element may be the same as or different from an acceptor making a pair with the second halogen element. A light emitter which is composed of the base material, at least two halogen elements behaving like a donor, and a metal behaving like an acceptor, is a novel composite material, and is applicable to the light-emitting layer as a light emitter with mixed color light emission. It is to be noted that M may be composed of two or more elements belonging to Group 2 to Group 13 of the periodic table like ZnMgS.

A known method may be used as a method for forming the first electrode, the second electrode, the first dielectric layer, and the second dielectric layer. For example, a vacuum evaporation method such as a resistance heating evaporation method, an electron beam evaporation (EB evaporation) method, or a hot wall method; a physical vapor deposition (PVD) method such as a sputtering method, an ion plating method, or an MEB method; a chemical vapor deposition (CVD) method such as a metal organic CVD method or a low-pressure hydride transport method; an atomic layer epitaxy (ALE) method; or the like can be used. Further, as a wet method, an inkjet method, a spin coating method, a printing method, a spray method, a squeegee method, an anodic oxidation method, a sol-gel method, or the like can be used.

A method for forming the light-emitting layer may be the same as the method for forming the electrodes or the dielectric layers. For example, a vacuum evaporation method such as a resistance heating evaporation method, an electron beam evaporation (EB evaporation) method, or a hot wall method; a physical vapor deposition (PVD) method such as a sputtering method, an ion plating method, or an MEB method; a chemical vapor deposition (CVD) method such as a metal organic CVD method or a low-pressure hydride transport CVD method; an atomic layer epitaxy (ALE) method; or the like can be used. Further, as a wet method, an inkjet method, a spin coating method, a printing method, a spray method, a squeegee method, an anodic oxidation method, a sol-gel method, or the like can be used.

A light-emitting element with a different structure is described with reference to FIG. 1C.

The light-emitting element has an element structure in which a first electrode 111 and a second electrode 116 are provided over a substrate 110, with a first dielectric layer 112, a first light-emitting layer 113, a second light-emitting layer 114, and a second dielectric layer 115 interposed between the first electrode 111 and the second electrode 116. Note that in this embodiment mode, the first electrode 111 and the second electrode 116 will be described below with an assumption that either may function as an anode or a cathode.

The material and formation method described above may be used for the substrate 110, the first electrode 111, the second electrode 116, the first dielectric layer 112, and the second dielectric layer 115. In a similar manner, for the first light-emitting layer 113 and the second light-emitting layer 114, the foregoing material and baking method may be used.

In a case of forming a light-emitting element with two light-emitting layers, as with the first light-emitting layer 113 and the second light-emitting layer 114, by having the same color of light emission, a light-emitting element with improved light emission intensity can be formed. Also, in a case of light emission of different colors, a light-emitting element having mixed colors can be obtained, and from a combination of this mixed color, a light-emitting element having white color light emission can be obtained. It is not necessary that the number of light-emitting layer be limited to two, and if necessary, a light-emitting element having two or more light-emitting layers can be formed.

As a structure of the light-emitting layer, for example, zinc sulfide (ZnS) is used for the base in the first light-emitting layer 113, and silver chloride (AgCl) is used as the additive material that becomes the luminescence center. Also, in the second light-emitting layer 114 formed over the first light-emitting layer 113, zinc sulfide (ZnS) is used for the base, and copper chloride (I) (CuCl) is used as the additive material. Consequently, mixed colors can be obtained from one light-emitting element. In this manner, by forming the light-emitting element using the same base material, degradation due to a difference of the base can be prevented, and lifetime of the light-emitting element can be lengthened. However, it is not necessary that the base in the first light-emitting layer and the second light-emitting layer be the same.

Also, in order to improve light emission intensity, calcium sulfide (CaS) and europium chloride (II) (EuCl₂) are used as the base and the additive material, respectively, in the first light-emitting layer 113, yttrium oxide (Y₂O₃) and europium chloride (III) (EuCl₃) are used as the base and the additive material, respectively, in the second light-emitting layer 114. Consequently, a light-emitting element with improved intensity even with single color light emission can be formed.

As a light-emitting element of the present invention, a light-emitting element that can be operated at low driving voltage can be obtained depending on mobility of a semiconductor forming a light-emitting layer. If light emission is possible at such low driving voltage, a light-emitting element with reduced power consumption can be obtained.

Note that this embodiment mode can be appropriately combined with another embodiment mode.

### Embodiment Mode 2

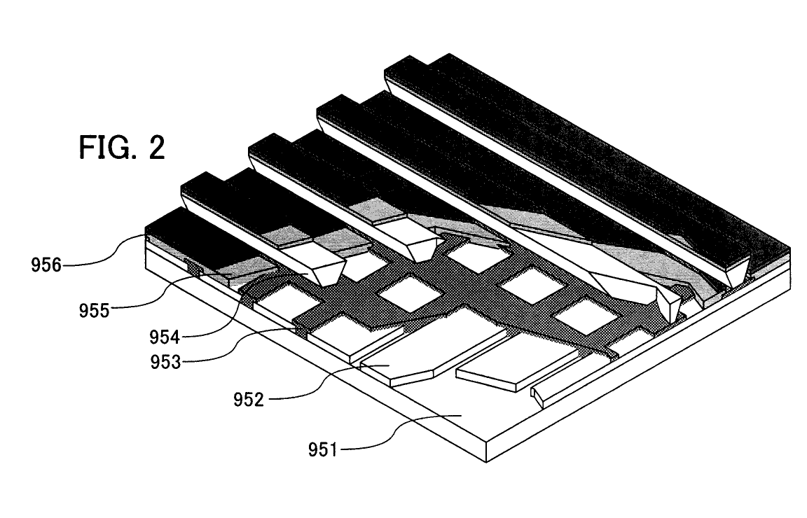

In this embodiment mode, a light-emitting device including the light-emitting element of the present invention is described with reference to FIG. 2.

A light-emitting device described in this embodiment mode is a passive light-emitting device in which a light-emitting element is driven without particularly providing an element for driving such as a transistor. FIG. 2 is a perspective view of a passive light-emitting device manufactured by applying the present invention.

In FIG. 2, over a substrate 951, a light-emitting layer 955 is provided between a first electrode 952 and a second electrode 956. Note that the light-emitting layer 955 includes the light-emitting layer described in Embodiment Mode 1.

An edge portion of the first electrode 952 is covered with an insulating layer 953. A partition layer 954 is provided over the insulating layer 953. Sidewalls of the partition layer 954 are slanted so that a distance between one of the sidewalls and the other becomes narrower toward a substrate surface. In other words, a cross-sectional surface in a short side direction of the partition layer 954 is trapezoidal, in which a base of side that is in contact with the insulating layer 953) is shorter than a top (a side that is not in contact with the insulating layer 953). In this manner, the partition layer 954 is provided, whereby defects of the light-emitting element due to static electricity or the like can be prevented. Further, in the passive light-emitting device also, driving with low power consumption can be carried out by including the light-emitting element of the present invention which operates at a low driving voltage.

Although one structure of a light-emitting element is described in this embodiment mode, it is not necessary to be bound to this structure. A dielectric layer may be formed over an electrode, and the light-emitting layer may have a stacked structure of a p-type semiconductor and an n-type semiconductor as shown in Embodiment Mode 1.

### Embodiment Mode 3

In this embodiment mode, a light-emitting device including the light-emitting element of the present invention is described.

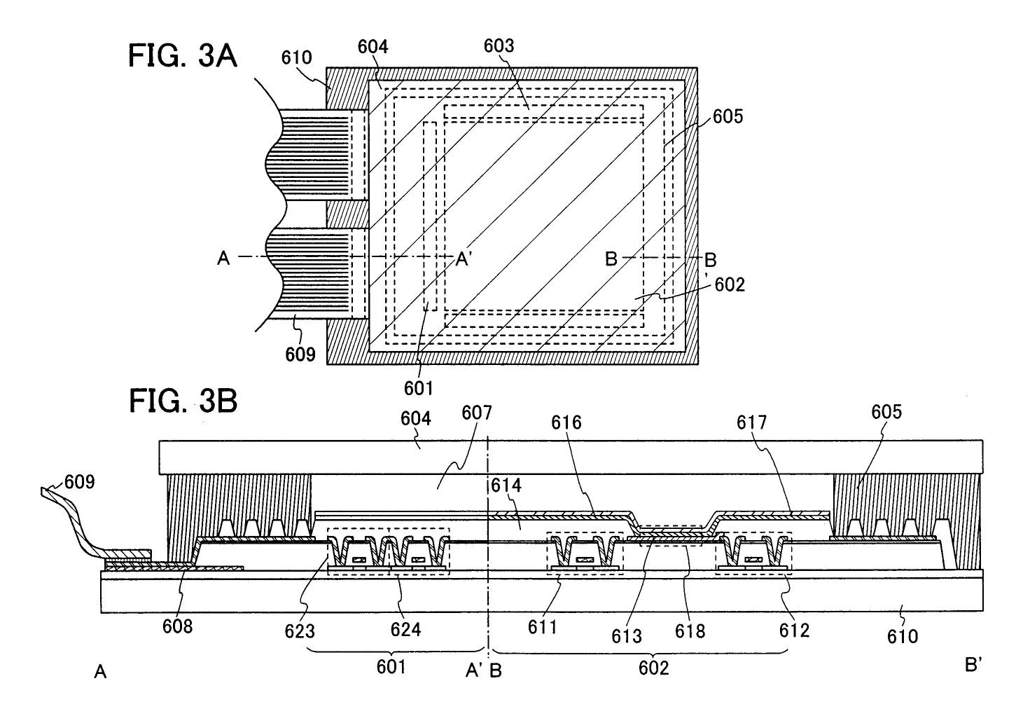

In this embodiment mode, an active light-emitting device in which driving of a light-emitting element is controlled by a transistor will be described. In this embodiment mode, a light-emitting device including the light-emitting element of the present invention in a pixel portion will be described with reference to FIGS. 3A and 3B. FIG. 3A is a top view showing the light-emitting device and FIG. 3B is a cross-sectional view of FIG. 3A taken along lines A-A′ and B-B′. A reference numeral 601 denotes a driver circuit portion (a source side driver circuit); 602 denotes a pixel portion; and 603 denotes a driver circuit portion (a gate side driver circuit), each of which is indicated by a dotted line. A reference numeral 604 denotes a sealing substrate; 605 denotes a sealant; and a portion surrounded by the sealant 605 is a space 607.

It is to be noted that a lead wiring 608 is a wiring for transmitting signals to be input to the source side driver circuit 601 and the gate side driver circuit 603 and receives a video signal, a clock signal, a start signal, a reset signal, and the like from an FPC (Flexible Printed Circuit) 609 that is an external input terminal. Although only the FPC is shown here, the FPC may be provided with a printed wiring board (PWB). The light-emitting device in the present specification includes not only a case of providing just the light-emitting device, but also a case in which the light-emitting device is attached with an FPC or a PWB.

Next, a cross-sectional structure will be explained with reference to FIG. 3B. The driver circuit portions and the pixel portion are formed over an element substrate 610. Here, the source side driver circuit 601 that is one of the driver circuit portions and one pixel in the pixel portion 602 are shown.

A CMOS circuit that is a combination of an n-channel TFT 623 and a p-channel TFT 624 is formed as the source side driver circuit 601. A TFT forming the driver circuit may be that of a known CMOS circuit, PMOS circuit, or NMOS circuit. A driver integration type in which a driver circuit is formed over a substrate is described in this embodiment mode, but it is not always necessary and a driver circuit can be formed not over a substrate but outside of a substrate. The structure of the TFT is not particularly limited, and a staggered TFT may be employed, or an inversely staggered TFT may be employed. Crystallinity of a semiconductor film used for the TFT is not particularly limited either, and an amorphous semiconductor film may be used, or a crystalline semiconductor film may be used. Furthermore, a semiconductor material is not particularly limited, and an inorganic compound may be used, or an organic compound may be used.

The pixel portion 602 includes a plurality of pixels, each of which includes a switching TFT 611, a current control TFT 612, and a first electrode 613 which is electrically connected to a drain of the current control TFT 612. It is to be noted that an insulator 614 is formed to cover an edge portion of the first electrode 613. Here, a positive type photosensitive acrylic resin film is used.

The insulator 614 is formed to have a curved surface with curvature at an upper edge portion or a lower edge portion thereof in order to obtain favorable coverage. For example, in the case of using positive type photosensitive acrylic as a material of the insulator 614, the insulator 614 is preferably formed to have a curved surface with a curvature radius (0.2 μm to 3 μm) only at an upper edge portion. Either a negative type which becomes insoluble in an etchant by light irradiation or a positive type which becomes soluble in an etchant by light irradiation can be used as the insulator 614.

Over the first electrode 613, a layer 616 including a light-emitting substance (also called a light-emitting layer) and a second electrode 617 are provided to form a light-emitting element 618. At least one of the first electrode 613 and the second electrode 617 has a light-transmitting property, and light emission from the light-emitting layer 616 can be extracted to the outside. Note that if both the first electrode 613 and the second electrode 617 are formed of a material with a light-transmitting property, light emission can be extracted from both an element substrate 610 side and a sealing substrate 604 side, and the light-emitting element 618 can be used for a dual-emission device.

The first electrode 613, the light-emitting layer 616, and the second electrode 617 can be formed by various methods. Specifically, they can be formed by a vacuum evaporation method such as a resistance heating evaporation method, an electron beam (EB) evaporation method, or a hot wall method; a physical vapor deposition (PVD) method such as a sputtering method, an ion plating method, or an MEB method; a chemical vapor deposition (CVD) method such as a metal organic CVD method or a low pressure hydride transport CVD method; an atomic layer epitaxy (ALE) method; or the like. Furthermore, an inkjet method, a spin coating method, a printing method, a spraying method, a squeegee method, an anodic oxidation method, a sol-gel method, or the like can be used. In addition, each electrode or each layer may be formed by using a different film formation method.

By attaching the sealing substrate 604 to the element substrate 610 with the sealant 605, a light-emitting element 618 is provided in the space 607 surrounded by the element substrate 610, the sealing substrate 604, and the sealant 605. The space 607 is filled with a filler, but there is also a case where the space 607 is filled with the sealant 605 or filled with an inert gas (nitrogen, argon, or the like).

An epoxy-based resin is preferably used for the sealant 605. It is preferable that the material does not allow penetration of moisture or oxygen as much as possible. As the sealing substrate 604, a plastic substrate formed of FRP (Fiberglass-Reinforced Plastics), PVF (polyvinyl fluoride), or Mylar; polyester or acrylic; or the like can be used instead of a glass substrate or a quartz substrate.

In the above manner, the light-emitting device including the light-emitting element of the present invention can be obtained.

A display device of the present invention includes the light-emitting element described in Embodiment Mode 1. Also, when two or more kinds of halogen compounds are used for the additive materials, a mixed color element, or a white color element from a combination of this mixed color, can be manufactured.

### Embodiment Mode 4

In this embodiment mode, an electronic appliance of the present invention which includes in its part the light-emitting device described in Embodiment Mode 3 will be described. The electronic appliance of the present invention includes the light-emitting element described in Embodiment Modes 1 to 3.

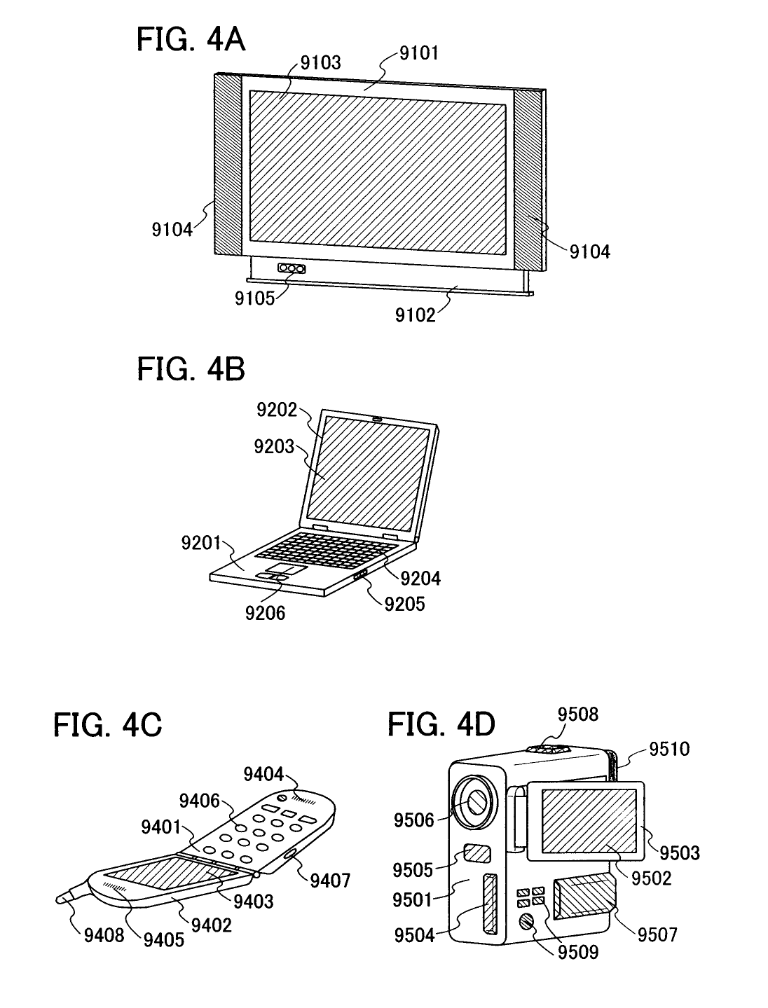

An example of the electronic appliance manufactured using the light-emitting device of the present invention is as follows: a camera such as a video camera or a digital camera, a goggle type display, a navigation system, a sound reproducing device (a car audio system, an audio component, or the like), a computer, a game machine, a portable information terminal (a mobile computer, a cellular phone, a mobile game machine, an electronic book, or the like), an image reproducing device having a recording medium (specifically, a device for reproducing a recording medium such as a digital versatile disc (DVD) and having a display device for displaying the image), or the like. Specific examples of these electronic appliances are shown in FIGS. 4A to FIG. 8.

FIG. 4A shows a television device according to the present invention, which includes a chassis 9101, a supporting base 9102, a display portion 9103, a speaker portion 9104, a video input terminal 9105, and the like. In this television device, the display portion 9103 includes light-emitting elements similar to those described in Embodiment Modes 1 to 3, which are arranged in matrix. Consequently, in a case of a mixed color or white color light-emitting element, it is necessary to form a color filter such as for a liquid crystal.

FIG. 4B shows a computer according to the present invention, which includes a main body 9201, a chassis 9202, a display portion 9203, a keyboard 9204, an external connection port 9205, a pointing mouse 9206, and the like. In this computer, the display portion 9203 includes light-emitting elements similar to those described in Embodiment Modes 1 to 3, which are arranged in matrix.

FIG. 4C shows a cellular phone according to the present invention, which includes a main body 9401, a chassis 9402, a display portion 9403, an audio input portion 9404, an audio output portion 9405, an operation key 9406, an external connection port 9407, an antenna 9408, and the like. In this cellular phone, the display portion 9403 includes light-emitting elements similar to those described in Embodiment Modes 1 to 3, which are arranged in matrix.

FIG. 4D shows a camera according to the present invention, which includes a main body 9501, a display portion 9502, a chassis 9503, an external connection port 9504, a remote control receiving portion 9505, an image receiving portion 9506, a battery 9507, an audio input portion 9508, operation keys 9509, an eye piece portion 9510, and the like. In this camera, the display portion 9502 includes light-emitting elements similar to those described in Embodiment Modes 1 to 3, which are arranged in matrix.

In the above manner, an application range of the light-emitting device of the present invention is extremely wide, and this light-emitting device can be applied to electronic appliances of a variety of fields.

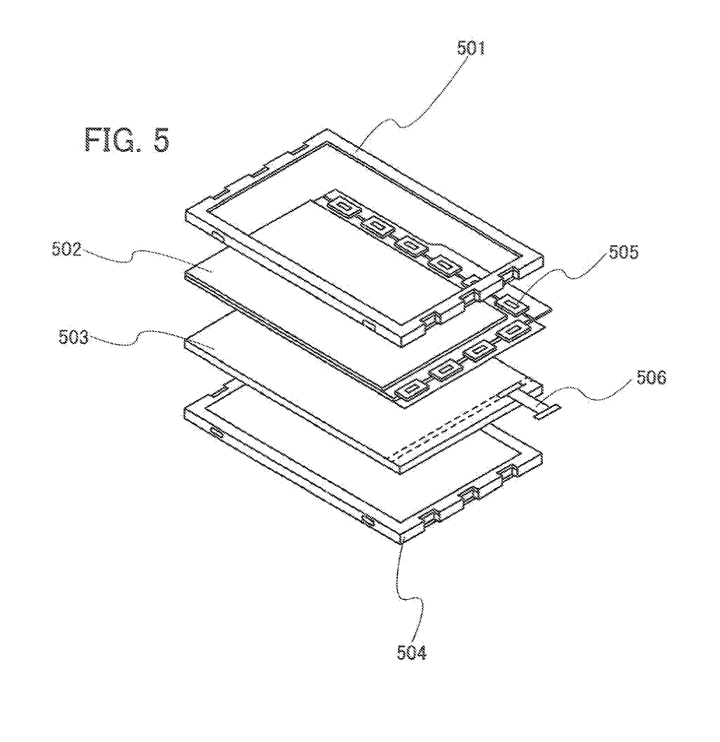

Further, since the light-emitting device of the present invention includes a light-emitting element that emits mixed color or white color light, it can also be used for a lighting device. One mode in which a light-emitting element of the present invention is used in a lighting device is described with reference to FIG. 5.

FIG. 5 shows an example of a liquid crystal display device using the light-emitting device of the present invention as a backlight. The liquid crystal display device shown in FIG. 5 includes a chassis 501, a liquid crystal layer 502, a backlight 503, and a chassis 504. The liquid crystal layer 502 is connected to a driver IC 505. The light-emitting device of the present invention is used as the backlight 503, to which current is supplied through a terminal 506.

By using the light-emitting device of the present invention as a backlight of a liquid crystal display device, a backlight with long life that is unique to an inorganic EL can be obtained. Since the light-emitting device of the present invention is a plane-emission light-emitting device and can be formed to have a large area, a larger-area backlight can be obtained and a larger-area liquid crystal display device can also be obtained. Furthermore, since the light-emitting device is thin, reduction in thickness of the display device is also possible.

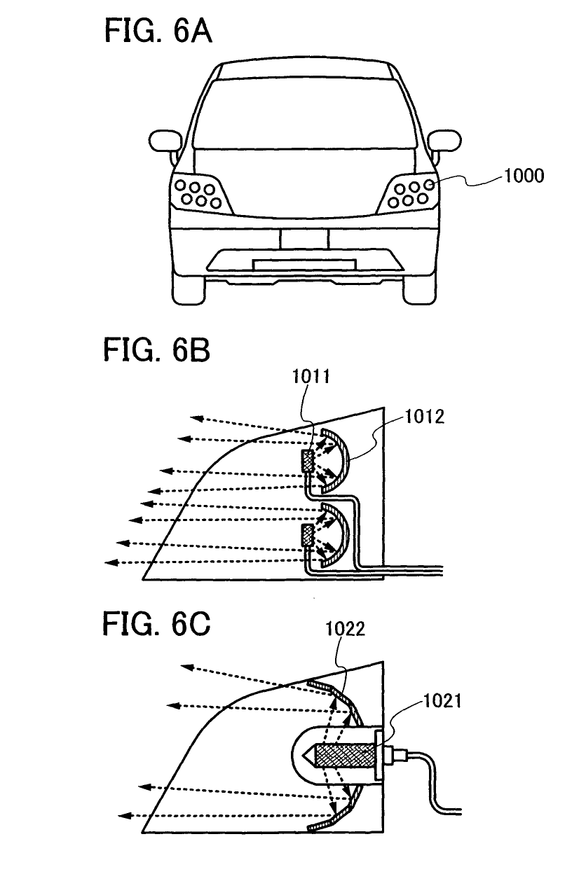

Furthermore, since a light-emitting device to which the present invention is applied can emit light with high luminance, it can be used as a headlight of a car, bicycle, ship, or the like. FIGS. 6A to 6C show an example in which the light-emitting device to which the present invention is applied is used as a headlight of a car. FIG. 6B is an enlarged cross-sectional view showing a headlight 1000 of FIG. 6A. In FIG. 6B, the light-emitting device of the present invention is used as a light source 1011. Light emitted from the light source 1011 reflects off a reflector 1012 and is extracted to the outside. As shown in FIG. 6B, light with higher luminance can be obtained by using a plurality of light sources. FIG. 6C is an example in which a light-emitting device of the present invention that is manufactured in a cylindrical shape is used as a light source. Light emission from the light source 1021 reflects off a reflector 1022 and is extracted to the outside.

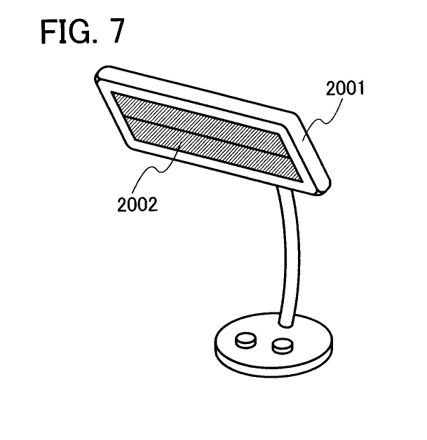

FIG. 7 shows an example in which the light-emitting device to which the present invention is applied is used as a desk lamp which is a lighting system. The desk lamp shown in FIG. 7 includes a chassis 2001 and a light source 2002, and the light-emitting device of the present invention is used for the light source 2002. Since the light-emitting device of the present invention is capable of light emission with high luminance, this desk lamp can illuminate hands when fine handwork is required or the like.

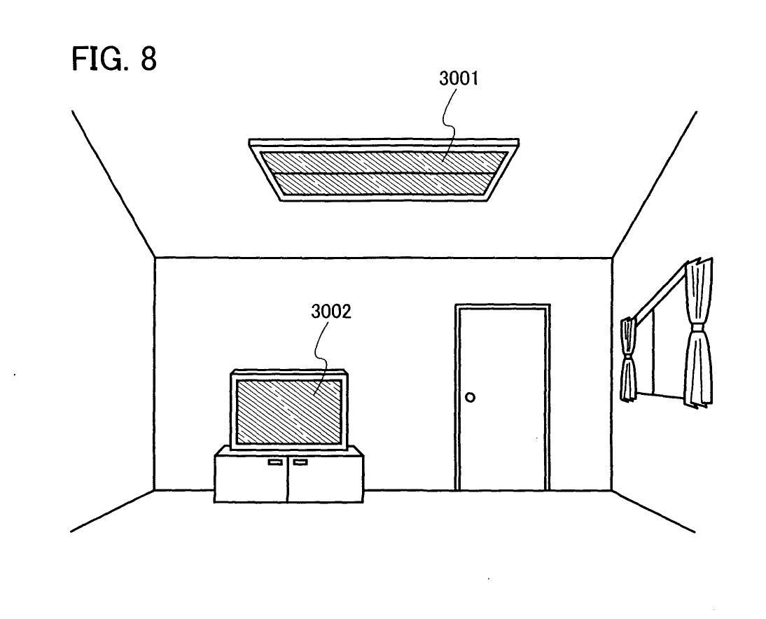

FIG. 8 shows an example in which the light-emitting device to which the present invention is applied is used for an indoor lighting system 3001. Since the light-emitting device of the present invention can have a large area, it can be used for a large-area lighting system. In addition, since the light-emitting device of the present invention is thin and power consumption is low, it can be used for a thin lighting system with low power consumption.

In this manner, a television device 3002 according to the present invention like the one described in FIG. 4A can be set up in a room using as the indoor lighting system 3001 the light-emitting device to which the present invention is applied, to view public broadcasts and movies. In such a case, since power consumptions of both devices are low, strong visuals can be viewed in a well-lit room without worrying about electricity cost.

The lighting systems are not limited to those exemplified in FIGS. 6A to 8, and the light-emitting device of the present invention can be applied to lighting systems in various modes, including lighting systems for houses and public facilities. In such a case, a light emission medium of the lighting system of the present invention is a thin film, which increases design freedom. Accordingly, various elaborately-designed products can be provided to the marketplace.

### Embodiment Mode 5

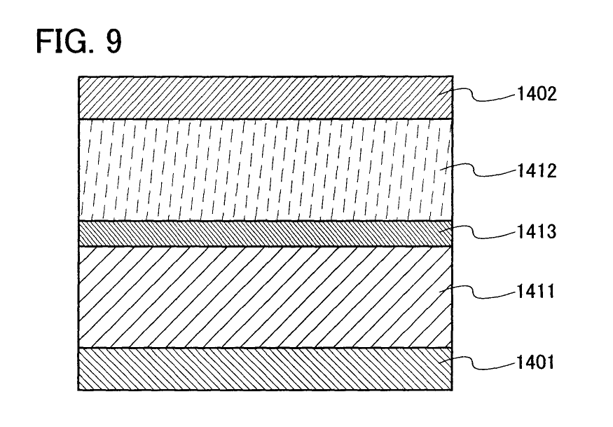

In this embodiment mode, a mode of a light-emitting element with a structure in which a plurality of light-emitting units of the present invention are stacked (hereinafter referred to as a stacked element) will be described with reference to FIG. 9. This light-emitting element has a plurality of light-emitting units between a first electrode and a second electrode. The light-emitting unit has a structure similar to the light-emitting layer of Embodiment Modes 1 to 3; for example, the light-emitting unit is a light-emitting layer interposed between two dielectric layers; a light-emitting layer in contact with one dielectric layer; a light-emitting layer only; or two or more layers of light-emitting layers.

In FIG. 9, a first light-emitting unit 1411 and a second light-emitting unit 1412 are stacked between a first electrode 1401 and a second electrode 1402. Materials similar to those in Embodiment Modes 1 to 3 can be applied to the first electrode 1401 and the second electrode 1402. Furthermore, it is not necessary that the first light-emitting unit 1411 and the second light-emitting unit 1412 have the same structure.

A charge generation layer 1413 may be a complex of an organic compound and a metal oxide, or it may be a third electrode. The complex of an organic compound and a metal oxide is constituted by an organic compound and a metal oxide such as V₂O₅, MoO₃, or WO₃. As the organic compound, various compounds such as an aromatic amine compound, a carbazole derivative, aromatic hydrocarbon, and a high molecular compound (oligomer, dendrimer, polymer, or the like) can be used. It is to be noted that the organic compound having a hole mobility of 10⁻⁶ cm²/Vs or greater is preferably used as a hole transporting organic compound. However, other material than the above materials may be used as long as the material has higher hole transporting property than electron transporting property. Since the complex of an organic compound and a metal oxide has an excellent carrier injecting property and carrier transporting property, low voltage drive and low current drive can be realized. In a case of an electrode, a transparent material or a reflecting material may be used.

The charge generation layer 1413 may be formed using a combination of the complex of an organic compound and a metal oxide, and other material. For example, a layer containing the complex of an organic compound and a metal oxide, and a layer containing a compound selected from electron donating materials and a compound having a high electron transporting property may be combined to form the charge generation layer 1413. Alternatively, a layer containing the complex of an organic compound and a metal oxide, and a transparent conductive film may be combined to form the charge generation layer 1413.

In any case, it is acceptable as long as the charge generation layer 1413 interposed between the first light-emitting unit 1411 and the second light-emitting unit 1412 injects electrons to the light-emitting unit on one side and injects holes to the light-emitting unit on the other side when a voltage is applied to the first electrode 1401 and the second electrode 1402.

Although the light-emitting element having two light-emitting units is described in this embodiment mode, a light-emitting element in which three or more light-emitting units are stacked can be employed in a similar way. By arranging a plurality of light-emitting units that are partitioned by an electrically insulating charge generation layer between a pair of electrodes, as in the light-emitting element according to this embodiment mode, an element having the long life in a high luminance region can be realized while keeping a current density low. In addition, in a case where the light-emitting element is applied to a lighting system, for example, uniform light emission in a large area is possible because voltage drop due to resistance of an electrode material can be decreased. Furthermore, in the case where the light-emitting element is applied to a display device, a display device with a high contrast which can be driven at a low voltage and consumes low power can be realized.

It is to be noted that this embodiment mode can be appropriately combined with other embodiment modes.

### Embodiment Mode 6

In this embodiment mode, a light-emitting device having a light-emitting element manufactured by applying the present invention will be described.

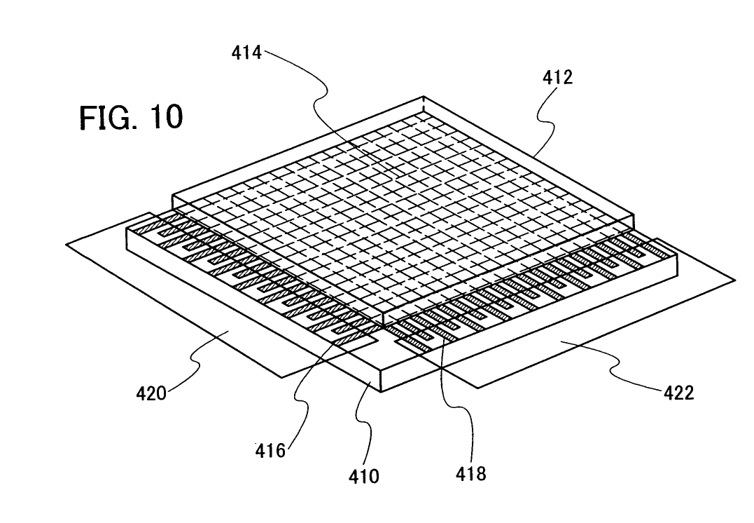

In this embodiment mode, a display device as one mode of the light-emitting device will be described with reference to FIGS. 10 to 13B. FIG. 10 is a configuration diagram showing a main part of the display device.

Over a substrate 410, a first electrode 416 and a second electrode 418 that extends in a direction intersecting with the first electrode 416 are provided. An EL layer similar to those described in Embodiment Modes 1 to 5 is provided at least at the intersection of the first electrode 416 and the second electrode 418, whereby a light-emitting element is formed. In a display device of FIG. 10, a plurality of first electrodes 416 and a plurality of second electrodes 418 are placed and light-emitting elements to be pixels are arranged in matrix, whereby a display portion 414 is formed. In the display portion 414, light emission and non-light emission of each light-emitting element are controlled by controlling potentials of the first electrode 416 and the second electrode 418. In this manner, the display portion 414 can display moving images and still images.

In this display device, a signal for displaying a picture is applied to each of the first electrode 416 extending in one direction over the substrate 410 and the second electrode 418 that intersects with the first electrode 416, and light emission and non-light emission of a light-emitting element are selected. In other words, this is a simple matrix display device of which the pixel is driven mostly by a signal given from an external circuit. A display device like this has a simple structure and can be manufactured easily even when the area is enlarged.

A counter substrate 412 may be provided as necessary, and it can serve as a protective material when provided to be adjusted to the position of the display portion 414. The counter substrate 412 does not have to be a hard plate material; and a resin film or a resin material may be applied instead. The first electrode 416 and the second electrode 418 are led to ends of the substrate 410 to form terminals to be connected to external circuits. In other words, the first electrode 416 and the second electrode 418 are in contract with first and second flexible wiring boards 420 and 422 at the ends of the substrate 410. The external circuits include a power supply circuit, a tuner circuit, or the like, in addition to a controller circuit that controls a video signal.

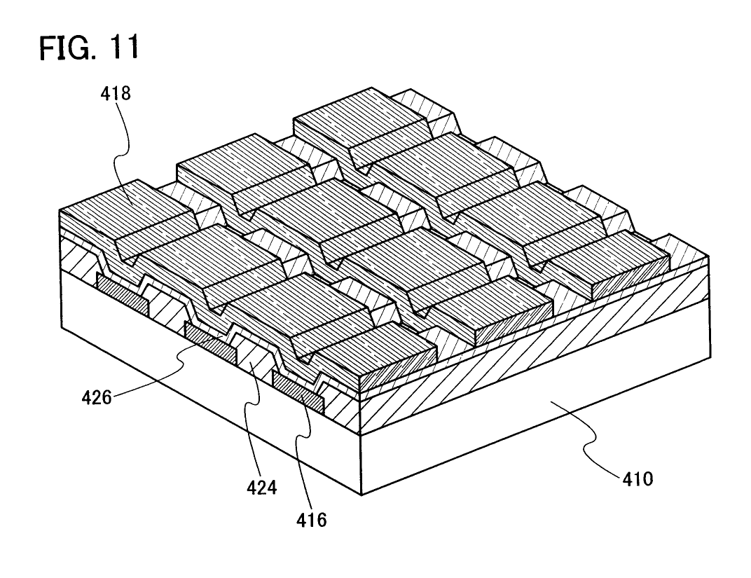

FIG. 11 is a partial enlarged view showing a structure of the display portion 414 in FIG. 10. A partition layer 424 is formed on an edge portion of the first electrode 416 formed over the substrate 410. An EL layer 426 is formed at least over an exposed surface of the first electrode 416. The second electrode 418 is formed over the EL layer 426. The second electrode 418 intersects with the first electrode 416, so it extends over the partition layer 424 as well. The partition layer 424 is formed using an insulating material so that short-circuiting between the first electrode 416 and the second electrode 418 is prevented. In a portion where the partition layer 424 covers the edge portion of the first electrode 416, an edge portion of the partition layer 424 is sloped so as not to make a steep step, and has a so-called tapered shape. In the case where the partition layer 424 has such a shape, coverage of the EL layer 426 and the second electrode 418 improves, and defects such as cracks or tear can be prevented.

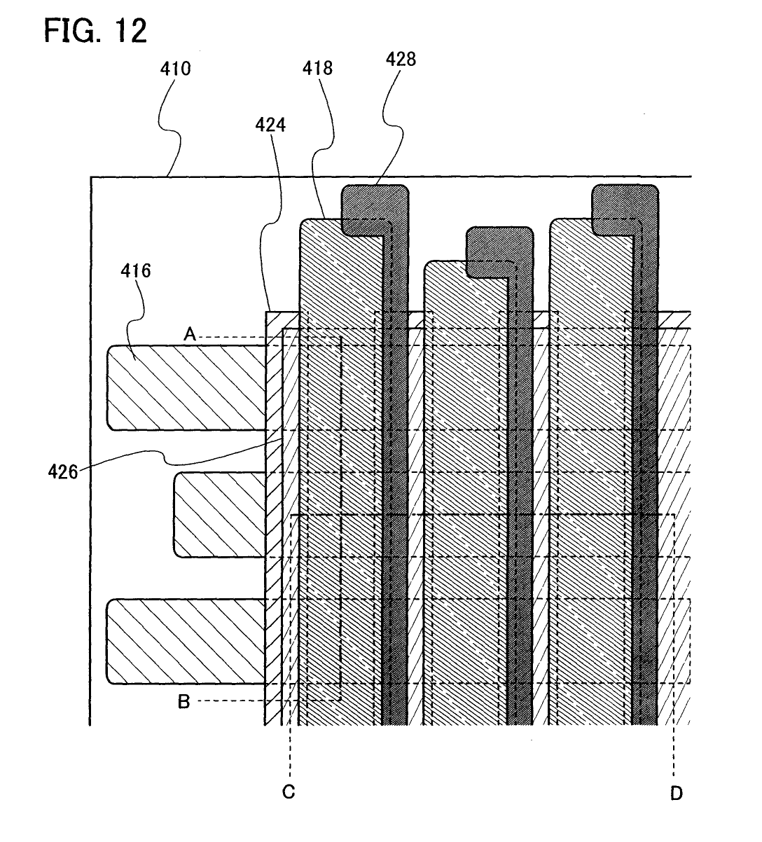

FIG. 12 is a plane view of the display portion 414 in FIG. 10, which shows the arrangement of the first electrode 416, the second electrode 418, the partition layer 424, and the EL layer 426 over the substrate 410. In a case where the second electrode 418 is formed of an oxide transparent conductive film of indium tin oxide, zinc oxide, or the like, an auxiliary electrode 428 is preferably provided so as to reduce resistance loss. In this case, the auxiliary electrode 428 may be formed using a refractory metal such as titanium, tungsten, chromium, or tantalum, or a combination of the refractory metal and a low resistance metal such as aluminum or silver.

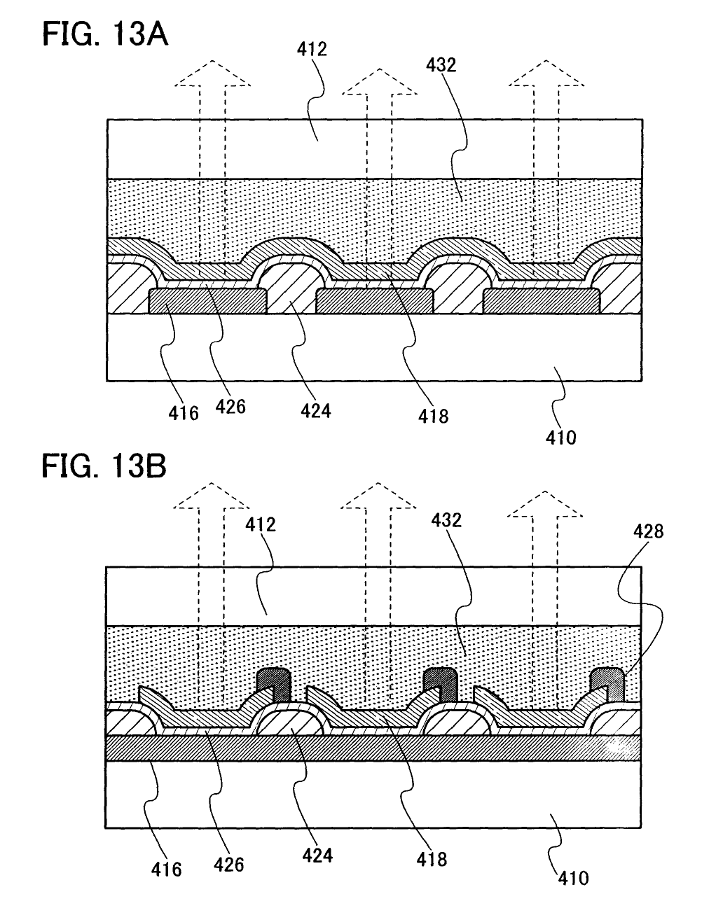

FIGS. 13A and 13B show cross-sectional views taken along a line A-B and a line C-D in FIG. 12, respectively. FIG. 13A is a cross-sectional view in which the first electrodes 416 in FIG. 11 are lined up, and FIG. 13B is a cross-sectional view in which the second electrodes 418 in FIG. 11 are lined up. The EL layer 426 is formed at the intersections of the first electrode 416 and the second electrode 418 which are over the substrate 410, and light-emitting elements are formed in these portions. Also, a filler 432 is provided between the substrate 410 and the counter substrate 412. The auxiliary electrode 428 shown in FIG. 13B is provided over the partition layer 424 and in contact with the second electrode 418. The auxiliary electrode 428 formed over the partition layer 424 does not block light from the light-emitting element formed at the intersection of the first electrode 416 and the second electrode 418; therefore, the emitted light can be efficiently utilized. In addition, with this structure, short-circuiting between the auxiliary electrode 428 and the first electrode 416 can be prevented.

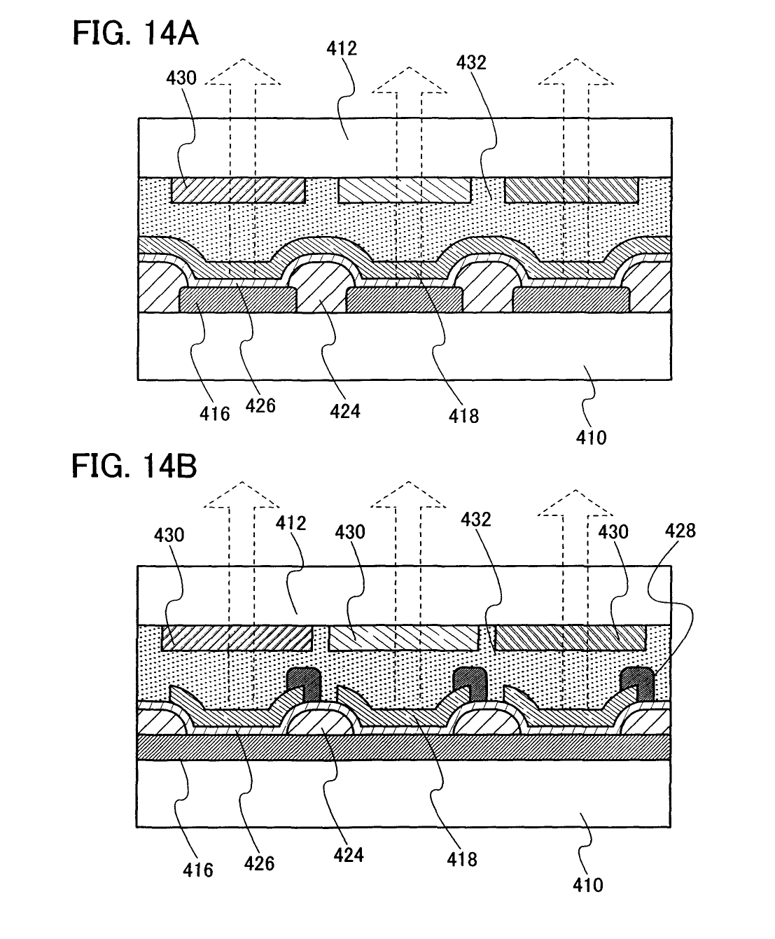

In FIGS. 14A and 14B, examples in which color conversion layers 430 are placed on the counter substrate 412 in FIG. 13A and 13B are shown. The color conversion layers 430 convert the wavelength of light emitted from the EL layer 426 so that the color of the light emission is changed. In this case, light emitted from the EL layer 426 is preferably blue light or ultraviolet light with high energy. When the color conversion layers 430 for converting light to red, green, and blue light are arranged, a display device that performs RGB full-color display can be obtained. Furthermore, the color conversion layer 430 can be replaced by a colored layer (color filter). In this case, the EL layer 426 may be structured to emit white color light. The filler 432 may be appropriately provided so as to fix the substrate 410 and the counter substrate 412 to each other.

In a display device utilizing the light-emitting element of this embodiment mode, light emission intensity and lifetime of the element can be increased by thinning an EL layer in the light-emitting element.

This application is based on Japanese Patent Application serial no. 2006-056994 filed in Japan Patent Office on Mar. 2 in 2006, the entire contents of which are hereby incorporated by reference.

1. A light-emitting device comprising:
a first electrode;
a light-emitting layer formed over the first electrode and comprising a base material and a luminescence center; and
a second electrode formed over the light-emitting layer,
wherein the base material contains a chalcogen element and at least one element selected from the group consisting of elements belonging to Group 2 to Group 13 of the periodic table, and
wherein the luminescence center contains at least one halogen element and at least one element selected from the group consisting of typical metal elements, transition metal elements, and rare earth elements.

2. The light-emitting device according to claim 1, wherein the base material is a compound selected from the group consisting of ZnO, ZnS, ZnSe, MgS, CaS, SrS, SrGa₂S₄, and ZnMgS.

3. The light-emitting device according to claim 1, wherein the luminescence center is a compound selected from the group consisting of CuF, CuF₂, CuCl, CuCl₂, CuBr, CuBr₂, CuI, CuI₂, AgBr, and AgI.

4. The light-emitting device according to claim 1, wherein the transition metal elements are Cu, Ag, and Au.

5. An electronic appliance comprising the light-emitting device according to claim 1.

6. A light-emitting device comprising:
a first electrode;
a dielectric layer formed over the first electrode;
a light-emitting layer formed over the dielectric layer and comprising a base material and a luminescence center; and
a second electrode formed over the light-emitting layer,
wherein the base material contains a chalcogen element and at least one element selected from the group consisting of elements belonging to Group 2 to Group 13 of the periodic table, and
wherein the luminescence center contains at least one halogen element and at least one element selected from the group consisting of typical metal elements, transition metal elements, and rare earth elements.

7. The light-emitting device according to claim 6, wherein the base material is a compound selected from the group consisting of ZnO, ZnS, ZnSe, MgS, CaS, SrS, SrGa₂S₄, and ZnMgS.

8. The light-emitting device according to claim 6, wherein the luminescence center is a compound selected from the group consisting of CuF, CuF₂, CuCl, CuCl₂, CuBr, CuBr₂, CuI, CuI₂, AgBr, and AgI.

9. The light-emitting device according to claim 6, wherein the transition metal elements are Cu, Ag, and Au.

10. The light-emitting device according to claim 6, wherein the dielectric layer comprises at least one material selected from the group consisting of acetal resin, an epoxy resin, methyl methacrylate, polyester, polyethylene, polystyrene, cyano ethyl cellulose, aluminum nitride boron nitride, titanate, strontium titanate, lithium titanate, lead titanate, tantalum pentoxide, bismuth oxide, calcium titanate, potassium niobate, silicon oxide, and aluminum oxide.

11. An electronic appliance comprising the light-emitting device according to claim 6.

12. A light-emitting device comprising:
a first electrode;
a first dielectric layer formed over the first electrode;
a light-emitting layer formed over the first dielectric layer and comprising a base material and a luminescence center;
a second dielectric layer formed over the light-emitting layer; and
a second electrode formed over the second dielectric layer,
wherein the base material contains a chalcogen element and at least one element selected from the group consisting of elements belonging to Group 2 to Group 13 of the periodic table, and
wherein the light-emitting center contains at least one halogen element and at least one element selected from the group consisting of typical metal elements, transition metal elements, and rare earth elements.

13. The light-emitting device according to claim 12, wherein the base material is a compound selected from the group consisting of ZnO, ZnS, ZnSe, MgS, CaS, SrS, SrGa₂S₄, and ZnMgS.

14. The light-emitting device according to claim 12, wherein the luminescence center is a compound selected from the group consisting of CuF, CuF₂, CuCl, CuCl₂, CuBr, CuBr₂, CuI, CuI₂, AgBr, and AgI.

15. The light-emitting device according to claim 12, wherein the transition metal elements are Cu, Ag, and Au.

16. The light-emitting device according to claim 12, wherein each of the first and second dielectric layers comprises at least one material selected from the group consisting of acetal resin, an epoxy resin, methyl methacrylate, polyester, polyethylene, polystyrene, cyano ethyl cellulose, aluminum nitride boron nitride, titanate, strontium titanate, lithium titanate, lead titanate, tantalum pentoxide, bismuth oxide, calcium titanate, potassium niobate, silicon oxide, and aluminum oxide.

17. An electronic appliance comprising the light-emitting device according to claim 12.

18. A lighting device comprising:
a first electrode;
a light-emitting layer formed over the first electrode and comprising a base material and a light-emitting center; and
a second electrode formed over the light-emitting layer,
wherein the base material contains a chalcogen element and at least one element selected from the group consisting of elements belonging to Group 2 to Group 13 of the periodic table, and
wherein the light-emitting center contains at least one halogen element and at least one element selected from the group consisting of typical metal elements, transition metal elements, and rare earth elements.

19. The lighting device according to claim 18, wherein the base material is a compound selected from the group consisting of ZnO, ZnS, ZnSe, MgS, CaS, SrS, SrGa₂S₄, and ZnMgS.

20. The lighting device according to claim 18, wherein the light-emitting center is a compound selected from the group consisting of CuF, CuF₂, CuCl, CuCl₂, CuBr, CuBr₂, CuI, CuI₂, AgBr, and AgI.

21. The lighting device according to claim 18, wherein the transition metal elements are Cu, Ag, and Au.

22. The lighting device according to claim 18, further comprising a dielectric layer between the first electrode and the light-emitting layer.

23. An electronic appliance comprising the lighting device according to claim 18.

24. A light-emitting device comprising:
a first electrode;
a light-emitting layer formed over the first electrode and comprising a compound represented by a composition formula of MX, an acceptor, a first donor, a second donor; and
a second electrode formed over the light-emitting layer,
wherein the compound has a crystal structure,
wherein M is an element selected from the group consisting of elements belonging to Group 2 to Group 13 of the periodic table,
wherein X is a chalcogen element, and
wherein the acceptor is an ion having lower valence than M.

25. The light-emitting device according to claim 24, wherein the light-emitting layer further comprises another acceptor which is an ion having lower valence than M.

26. The light-emitting device according to claim 24, wherein each of the first and second donors is an ion having lower valence than X.

27. The light-emitting device according to claim 24, wherein M is composed of two or more elements belonging to Group 2 to Group 13 of the periodic table.

28. The light-emitting device according to claim 24, wherein the crystal structure including at least one unit cell.

29. The light-emitting device according to claim 28, wherein a crystal system of the unit cell is one of cubic system, hexagonal system, tetragonal system, orthorhombic system, monoclinic system, and triclinic system, or a combination thereof.

30. The light-emitting device according to claim 24, wherein the compound is one selected from the group consisting of ZnO, ZnS, ZnSe, MgS, CaS, SrS, and ZnMgS.

31. An electronic appliance comprising the light-emitting device according to claim 24.

32. A light-emitting device comprising:
a first electrode;
a light-emitting layer formed over the first electrode and comprising a compound represented by a composition formula of MX, a first acceptor, a second acceptor, a first donor, and a second donor; and
a second electrode formed over the light-emitting layer,
wherein the compound has a crystal structure,
wherein M is an element selected from the group consisting of elements belonging to Group 2 to Group 13 of the periodic table,
wherein X is a chalcogen element,
wherein each of the first and second acceptors is an element selected from the group consisting of typical metal elements, transition metal elements, and rare earth elements,
wherein the first donor is a first halogen element, and
wherein the second donor is a second halogen element other than the first halogen element.

33. The light-emitting device according to claim 32, wherein the crystal structure including at least one unit cell.

34. The light-emitting device according to claim 33, wherein a crystal system of the unit cell is one of cubic system, hexagonal system, tetragonal system, orthorhombic system, monoclinic system, and triclinic system, or a combination thereof.

35. The light-emitting device according to claim 32,
wherein a first lattice point of the X is replaced by the first donor in the crystal structure,
wherein a second lattice point of the X is replaced by the second donor in the crystal structure,
wherein each of the first and second acceptors locates at a lattice point of M or an interstice in the crystal structure.

36. The light-emitting device according to claim 32, wherein the compound is one selected from the group consisting of ZnO, ZnS, ZnSe, MgS, CaS, and SrS.

37. The light-emitting device according to claim 32, wherein the first acceptor is the same as the second acceptor.

38. An electronic appliance comprising the light-emitting device according to claim 32.
